(19) United States
(12) Patent Application Publication
(10) Pub. No.: US 2007/0241668 A1
(43) Pub. Date: Oct. 18, 2007

(54) Organic, Eelectro-Optical Element With Increased Decoupling Efficiency

(75) Inventors: Clemens Ottermann, Hattersheim (DE); Thomas Daubler, Mainz (DE); Steffen Reichel, Mehlingen (DE); Edgar Pawlowski, Stadingen-Elsheim (DE)

Correspondence Address: DEMONT & BREYER, LLC, 100 COMMONS WAY, HOLMDEL, NJ, 07733, US

(73) Assignee: SCHOTT AG, 55122 Mainz (DE)

(21) Appl. No.: 10/599,811

(22) PCT Filed: Apr. 22, 2005
(86) PCT No.: PCT/EP05/04356

§ 371 Date: Jun. 12, 2007

(30) Foreign Application Priority Data
Apr. 22, 2004 (DE) 10 2004 020 245.1

(51) Int. Cl. H05B 33/00; B05D 5/06; G02B 5/28

(52) U.S. Cl. 313/504; 359/589; 427/162; 427/585

(57) ABSTRACT

In order to obtain an increased inputs and/or extraction efficiency for light in an organic, electro-optical element, in particular in an OLED, the invention provides an organic, electro-optical element which comprises a substrate (2) and at least one electro-optical structure (4) which comprises an active layer with at least one organic, electro-optical material (61), the substrate having at least one antireflection coating (8, 10) with at least one layer, and the antireflection coating (8, 10) layer having a thickness and a refractive index for which the integral reflectivity at the boundary faces of the antireflection coating is minimal for light beams emerging from the active layer at all angles for a wavelength in the spectral region of the emission spectrum, or for which the integral reflectivity is at most 25 percent higher than the minimum.

The invention generally relates to electro-optical elements and methods for their manufacture. In particular the invention relates to an organic electro-optical element with increased extraction efficiency, and to a method for its manufacture.

Organic light-emitting diodes (OLEDs) can already be manufactured with very good internal quantum efficiencies (number of photons per injected electron). As a result, OLED layer structures with internal quantum efficiencies of 85% are already known. However, the efficiency of OLEDs is clearly limited by coupling-out losses. Reflection losses occur at the existing boundary faces of adjacent media with different refractive indices. In particular, a particularly high jump in refractive index occurs when light is coupled out from the surface of the OLED and when it enters the carrier substrate. This jump in the refractive index leads to the total reflection of light which is incident on the boundary face from the interior of the OLED at an angle which is greater than the limiting angle. This in turn reduces the spatial angle at which the radiation can be coupled out. As a result, the following approximation applies to the fraction η of the radiation which can be coupled out:
η≈0.5·n²,
n designating the largest refractive index of the individual layers of the OLED.

In general, an OLED comprises an organic, electroluminescent layer whose light is coupled out by a transparent, conductive electrode layer, for example composed of indium-tin oxide (ITO), and a transparent carrier, such as in particular a glass carrier, a glass ceramic or polymer film with preferably barrier coating. Typical values for the refractive indices are here n=1.6-1.7 for the organic electroluminescence layer, n=1.6-2.0 for the ITO layer, n≈1.5 for the carrier material and n≈1.0 for the surrounding air. High reflection losses thus occur at the two boundary faces of the carrier.

Various approaches to solving this problem have been tried. US 2001/0055673 A1 has already proposed, for example, to apply a multi-layer interference layer to both sides of a flat substrate.

US 2002/0094422 A1 also discloses an OLED in which an intermediate layer which has a varying refractive index is arranged between the transparent ITO electrode layer and the substrate, the refractive index at the boundary faces of the intermediate layer having in each case the refractive index of the adjacent materials.

Furthermore there is the possibility of manufacturing periodic structures. Here, an attempt has been made, inter alia, to use the extracting efficiency by means of distributed feedback grills or structures with a two-dimensional photonic band gap. Such an arrangement is described, for example, in “A high-extraction efficiency nanopatterned organic light emitting diode”, Appl. Phys. Lett. Vol. 82, Num. 21, 3779 et seq. Likewise, a quasi-periodic arrangement of SiO₂ spheres on the glass carrier has been tested. However, periodic structures have distinct dispersive properties so that they change the spectral composition of the extracted light, in particular also as a function of direction. In addition, the manufacture of such layers requires additional working steps with considerable expenditure.

Microoptical elements such as lenses or truncated cones which are fitted onto the OLED structures are also known. However, there is the problem here that these structures are effective only if the active surface of the OLED is smaller than the surface component which is assigned to this surface. As a result, even though the extraction efficiency is considerably increased, the light-emitting surface of the OLED is simultaneously reduced so that in this way no significant increase in the overall brightness is achieved. These solutions to the problem are therefore at most suitable for obtaining a higher light intensity in pixel displays in which intermediate spaces between the individual OLED structures which are not illuminated in any case are present.

The use of intermediate layers with a low refractive index has been tested as a further possibility. In particular, for this purpose aerogel intermediate layers have been tested. This solution provides a significant increase in the extraction efficiency. However, there is a disadvantage here in the sensitivity of the OLED structure to chemical ambient influences. OLEDs degrade generally very quickly under the effect of water or oxygen. However, the porous OLED layers only have a small barrier effect to such reactive substances. Aerogels can even act as a sponge which absorbs degrading substances even during the manufacture of the OLED and stores and subsequently transmits them to the layer structure of the OLED. Even though an OLED which is manufactured in this way therefore exhibits particularly high extraction efficiencies, it has only a low degree of suitability for OLEDs with a long service life.

These previously known arrangements for increasing the extraction efficiency are either comparatively costly to implement or have other disadvantages such as adversely affecting the service life.

The object of the invention is therefore to provide an organic electro-optical element with increased extraction efficiency which can be manufactured easily and whose service life is not adversely affected by the measures for increasing the extraction efficiency. This object is already achieved in a very surprisingly simple way by means of an organic, electro-optical element, as well as a method for manufacturing an organic, electro-optical element as claimed in the independent claims. Advantageous developments are the subject matter of the respective dependent claims.

Accordingly, an organic, electro-optical element according to the invention comprises a substrate and at least one electro-optical structure which comprises an active layer with at least one organic, electro-optical material, the substrate having at least one antireflection coating with at least one layer, and the antireflection coating layer having a thickness and a refractive index for which the integral reflectivity at the boundary faces of the antireflection coating is minimal for light beams emerging from the active layer at all angles and for a wavelength in the spectral region of the emitted light, or for which the integral reflectivity is at most 25 percent, preferably 15 percent, particularly preferably 5 percent, higher than the minimum of the integral reflectivity.

The integral reflectivity is here the reflectivity which is integrated over all the emission angles of light beams which emerge from the active layer, at the boundary faces of the antireflection coating.

The minimum of the integral reflectivity is also understood to be the minimum value of the integral reflectivity which can be obtained when varying the values for the refractive index and coating thickness of the antireflection coating, for example in the case of a single-layer coating for the antireflection coating under conditions which are otherwise unchanged. In this context, the refractive index of the coating according to one embodiment of the invention can be applied without dispersion and uniformly over the entire thickness of the coating.

An antireflected substrate, in particular glass substrate with an antireflection coating with at least one layer which has a thickness and a refractive index for which the integral reflectivity at the boundary faces of the antireflection coating for light beams emerging for all angles in the active layer is minimal, or for which the integral reflectivity is at most 25 percent higher than the minimum, can be used as a carrier for an organic, electro-optical element such as, in particular, an organic, light-emitting diode, but of course also as a carrier or attachment for other light-emitting devices.

Furthermore, a substrate which is provided with an antireflection coating according to the invention, such as for example a transparent glass substrate or plastic substrate, can also be used for all further applications in which light is not only incident perpendicular to the substrate or transmitted through it. Here too, improved antireflection can already be achieved particularly advantageously even with just a single-layer antireflection coating. Of course, the invention can also be extended to multi-layer antireflection coatings for these applications.

Accordingly, such a substrate according to the invention generally has an antireflection coating with at least one layer such as is specifically described here for electro-optical elements, in particular organic, electro-optical elements and their manufacture. For example, optical devices such as, for example, optical components, panes, in particular window panes for buildings—both simple window panes and architecture glass windows or vehicle windows, for example windows for aircraft, ships and land vehicles—or else illumination bodies such as incandescent bulbs or fluorescent tubes with one or more antireflection coatings according to the invention can also be provided with optimized integral reflectivity. Optical components with antireflection coatings according to the invention may be, for example, lenses, or spectacle glasses, prisms or optical filters. The invention is suitable here in particular for such optical devices which are designed for transmitting light which emerges from the substrate or enters the substrate over a wide angular range.

The extraction efficiency or input efficiency of light which passes through the substrate is increased significantly by an antireflection coating compared to a noncoated substrate since the antireflection at least partially suppresses back reflections. According to the invention the thickness of the coating and the refractive index of the antireflection coating are not optimized to perpendicular incidence, which gives rise to a coating thickness, known from the prior art, of a quarter of the wavelength, but rather instead all the possible directions of emitted light beams are taken into account.

By virtue of the arrangement according to the invention, it is already possible here with a simple, single-layer antireflection coating to increase the transmission from the active layer into the substrate and/or when the light emerges on the visible side of the element by a factor of two, which also correspondingly entails a significant increase in the entire external quantum efficiency.

According to one embodiment of the invention, the coating thickness and the refractive index of the antireflection coating are selected here in such a way that the integral of the reflectivity of the antireflection coating,

$$I ( {n}_{1} , {n}_{2} , {n}_{3} , d ) = {\int }_{0}^{π / 2} R ( {n}_{1} , {n}_{2} , {n}_{3} , d , θ ) sin ( θ ) ⅆ θ \qquad 1 )$$

is minimal or deviates from the minimum value by 25 percent at most. Here, n₂ designates the refractive index of the antireflection coating, n₁ and n₃ designate the refractive indices of the media adjacent to the antireflection coating, θ designates the angle of the emitted light with respect to the perpendicular to the boundary face of the antireflection coating facing the emitter, and d designates the coating thickness of the antireflection coating.

For the reflectivity R(n₁, n₂, n₃, d, θ) it is possible, while assuming identical emission probability for TE-polarized and TM-polarized light, or for unpolarized light, to postulate the following:

$$R ( {n}_{1} , {n}_{2} , {n}_{3} , d , θ ) = \frac{{R}_{TE} + {R}_{TM}}{2} , where \qquad 2 )$$

R_{TE} and R_{TM} are the reflection coefficients for TE-polarized or TM-polarized light. The following applies for the reflection coefficients:

$$\begin{matrix}{R}_{TE} = \frac{{r}_{12}^{2} + {r}_{23}^{2} + 2 {r}_{12} {r}_{23} cos ( 2 β )}{1 + {r}_{12}^{2} {r}_{23}^{2} + 2 {r}_{12} {r}_{23} cos ( 2 β )} , where & 3 ) \\ {r}_{12} = \frac{{n}_{1} cos ( {α}_{1} ) - {n}_{2} cos ( {α}_{2} )}{{n}_{1} cos ( {α}_{1} ) + {n}_{2} cos ( {α}_{2} )} , and & 3 a ) \\ {r}_{23} = \frac{{n}_{2} cos ( {α}_{2} ) - {n}_{3} cos ( {α}_{3} )}{{n}_{2} cos ( {α}_{2} ) + {n}_{3} cos ( {α}_{3} )} , or & 3 b ) \\ {R}_{TM} = \frac{{r}_{12}^{2} + {r}_{23}^{2} + 2 {r}_{12} {r}_{23} cos ( 2 β )}{1 + {r}_{12}^{2} {r}_{23}^{2} + 2 {r}_{12} {r}_{23} cos ( 2 β )} , where & 4 ) \\ {r}_{12} = \frac{{n}_{2} cos ( {α}_{1} ) - {n}_{1} cos ( {α}_{2} )}{{n}_{2} cos ( {α}_{1} ) + {n}_{1} cos ( {α}_{2} )} , and & 4 a ) \\ {r}_{23} = \frac{{n}_{3} cos ( {α}_{2} ) - {n}_{2} cos ( {α}_{3} )}{{n}_{3} cos ( {α}_{2} ) + {n}_{2} cos ( {α}_{3} )} . & 4 b )\end{matrix}$$

Also, for the parameter β the following applies:

$$β = \frac{2 π}{{λ}_{0}} {n}_{2} d cos ( {α}_{2} ) . \qquad 5 )$$

The angle α₁ designates here the angle measured with respect to the perpendicular to the boundary face, of a light beam which is incident on the antireflection coating, and thus corresponds to the angle θ. The angle α₂ is the angle, measured with respect to the perpendicular to the boundary face, of the light beam which is refracted at the boundary face between the medium with the refractive index n₁ and the antireflection coating, and which travels in the antireflection coating. The angle α₃ also designates the angle of the light beam which is refracted once more at the opposite boundary face to the medium with the refractive index n₃ and travels in this medium. The wavelength of the light in the vacuum is designated by λ₀. In the case of absorptive media, the refractive indices are to be correspondingly replaced by the complex indices N=n+ik.

Very surprisingly it becomes apparent that the antireflection coating which is embodied as described above with minimal reflectivity or reflectivity which deviates from the minimum only by 25% at most, generally has very much thicker coating thicknesses than are customarily used for antireflection coatings. A good antireflex effect can already be achieved with a substrate with an antireflection coating with at least one layer, in which substrate the antireflection coating layer, preferably all the antireflection coating layers in the case of a multi-layer antireflection coating, have an optical thickness of at least ⅜ of a wavelength of the transmission spectrum or emission spectrum, preferably even at least half a wavelength. The wavelength to which the optical thickness refers depends here preferably on the respective application. In the case of a substrate for an electro-optical element or an illumination element, this wavelength is preferably a wavelength of the spectral region of the emission spectrum, particularly preferably of the central wavelength of the spectrum which is emitted by the element or the central wavelength of the emission spectrum which is weighted with the sensitivity of the eyes. In the case of a window glass or a lens it is analogously possible to use the average wavelength of the visible spectrum or of the visible spectrum weighted with the sensitive of the eyes in order to calculate the layer thickness.

The integral reflectivity is generally dependent on the coating thickness and the refractive indices of the antireflection coating n₂ and those of the adjacent media n₂ and n₃, the refractive indices of the adjacent media being able to be predefined by presetting the material. For example, glass can be used as a substrate with a refractive index of n₃=1.45 and indium-tin oxide as a conductive transparent electrode material.

It is obvious to a person skilled in the art that a minimum integral reflectivity at the boundary face goes hand in hand with maximum transmission. Instead of determining the minimum integral reflectivity according to equation 1) it would also be possible to determine the maximum integral transmission for light beams emerging at all angles, for example, from an imaginary emitter in the active layer using the equations 2) to 5), the following applying for the integral transmission T (n₁, n₂, n₃, d, θ):
T(n₁,n₂,n₃,d,θ)=1−R(n₁,n₂,n₃,d,θ). 6)

It is also advantageous to select the coating thickness and the refractive index of the antireflection coating in such a way that the integral is optimized by means of the reflectivity which is weighted with the spectral intensity distribution of the emitted radiation. According to one development of this embodiment of the invention there is therefore provision for the antireflection coating layer to have a thickness and a refractive index for which the reflectivity which is integrated over all the angles of the light beams emerging from the active layer and the wavelengths of the spectral range of the emitted radiation, and which is weighted with the spectral intensity distribution, at the boundary faces of the antireflection coating is minimal, or at most 25 percent, preferably 15 percent, particularly preferably 5 percent, higher than the minimum.

This integral I (n₁, n₂, n₃, d) can be determined by:

$$\begin{matrix}I ( {n}_{1} ( λ ) , {n}_{2} ( λ ) , {n}_{3} ( λ ) , d ) = \\ {\int }_{{λ}_{1}}^{{λ}_{2}} {\int }_{0}^{π / 2} S ( λ ) \cdot R ( {n}_{1} ( λ ) , {n}_{2} ( λ ) , {n}_{3} ( λ ) , d , θ ) sin ( θ ) ⅆ θ ⅆ λ\end{matrix} \qquad 7 )$$

The same equations apply for the reflectivity R(n₁(λ), n₂(λ), n₃(λ), d, θ) as for equation (1) so that the equations 2)-5) can be advantageously used for the calculation. If, as in the equation 6, integration is also carried out over a wavelength range, it is however also necessary to take into account the dispersions of the media, or the dependence of the refractive indices n₁, n₂, n₃ on the wavelength. In this context, S(λ) designates the spectral intensity distribution function, R(n₁(λ), n₂(λ), n₃(λ), d, 0) designates the reflectivity as a function of the emission angle θ, coating thickness d and the wave-length-dependent refractive indices n₂(λ) of the antireflection coating and of the adjacent media, n₁(λ), n₃(λ), and λ₁ and λ₂ designate the integration limits of the spectral region. The values of the reflectivity R(n₁(λ), n₂(λ), n₃(λ), d, θ) are weighted with the spectral intensity distribution function S(λ). The limiting values λ₁ and λ₂ of the integration over the wavelength can, for example, designate the boundaries of the wavelength range of emission. However, it is also possible to select narrower boundaries or, a partial spectral region as integration boundaries. This is appropriate, inter alia, if, for example, the active layer also emits in wavelengths for which one or more of the materials used are opaque.

As a rule, the extrinsic, spectral emission probability can be determined more easily than the intrinsic emission probability of the active layer. However, this can generally be replaced for the determination of the layer thickness and of the refractive index in a first approximation by the extrinsic spectral distribution.

With an antireflection coating which is embodied in such a way it is possible to obtain optimum external quantum efficiency for the spectral region which is emitted by the active layer. However, the maximum of the subjective perceived brightness can deviate from the maximum achievable extraction efficiency owing to the sensitivity of the eyes which varies spectrally. Correspondingly, according to a further embodiment there is provision for the antireflection coating to have a thickness and a refractive index for which the reflectivity which is integrated over all the angles of the light beams emerging from the active layer, and the wavelengths of the spectral region of the emitted radiation, and which is weighted with the spectral intensity distribution and the spectral sensitivity of the eyes, at the boundary faces of the antireflection coating is minimal, or at most 25 percent, preferably 15 percent, particularly preferably 5 percent, higher than the minimum. This integral I (n₁, n₂, n₃, d) can be calculated by:

$$\begin{matrix}I ( {n}_{1} ( λ ) , {n}_{2} ( λ ) , {n}_{3} ( λ ) , d ) = \\ {\int }_{{λ}_{1}}^{{λ}_{2}} {\int }_{0}^{π / 2} S ( λ ) \cdot V ( λ ) \cdot R ( {n}_{1} ( λ ) , {n}_{2} ( λ ) , {n}_{3} ( λ ) , d , θ ) sin ( θ ) ⅆ θ ⅆ λ\end{matrix} \qquad 8 )$$

This equation corresponds to the equation 7) with the exception of the additional multiplication by the spectral sensitivity of the eyes V(λ) in the integrand.

The term organic, electro-optical element comprises, according to the invention, both an organic, electroluminescent or light-emitting element, such as an OLED, and a photovoltaic element which has an organic material as a photovoltaically active medium. In what follows, for the sake of simplicity the term OLED is also used generally for organic, light-converting elements, that is to say both for light-emitting and for photovoltaic elements, owing to the equivalent structure.

In this context, an electro-optical structure can be understood to be the coating structure of an OLED or of a correspondingly structured photovoltaic element. Such a structure comprises accordingly in general a first and second conductive layer between which an active layer which has the at least one electro-optical material is arranged. Active layers can be understood to be here, inter alia, layers which have MEH-PPV or Alq₃ (tris-(8-hydroxyquinolino)aluminum) as organic, electro-optical material. The first and second conductive layers which serve as electrodes for the electro-optical structure also generally have different ionization energy levels so that a difference in ionization energy level occurs between the two layers.

The mechanism of the generation of light in the electro-optical material of an OLED is based according to general understanding here on the recombination of electrons and holes, or the recombination of excitones with emission of light quanta. For this purpose, with voltage applied between first and second conductive layers, electrons are injected from the layer with the higher ionization energy level into the LUMO (lowest unoccupied molecular orbital) and from the layer with the lower ionization energy level holes are injected into the HOMO (highest occupied molecular orbital) of the electro-optical material, and they then combine there.

In a photovoltaic element, this process correspondingly occurs in reverse so that a voltage can be tapped between the first and second conductive layers.

In preferred embodiments of the invention, the substrate comprises glass, in particular calcium-sodium glass and/or plastic.

In order to determine layer thicknesses which are optimized in terms of the integral reflectivity of the antireflection coating, and refractive indices of the layers of a multi-layer coating it is possible, for example, to calculate the integral 1) by recursive application of the above equations 2) to 5) for the individual layers of the antireflection coating. In particular, a numerical calculation is appropriate here. Relevant computer programs or collections of specialist papers or specialist books relating to the calculation are known to a person skilled in the art.

In further developments of the invention, the antireflection coating comprises a plurality of layers, or a multiple-layer system with a combination of individual layers with a high refractive index, medium refractive index or low refractive index. For this purpose it is advantageous to make it possible to use the layer materials which are known from the recycling of optical components, such as titanium oxide, tantalum oxide, niobium boxide, hafnium oxide, aluminum oxide or silicon oxide but also nitride such as, for example, magnesium nitride. However, further coating materials which are known to a person skilled in the art or combinations and mixtures of these materials, in particular for generating layers with a medium refractive index, are to be provided for implementing the invention.

It also lies within the scope of the invention to specify a method for manufacturing an organic, electro-optical element with improved extraction and/or input efficiency for light, in particular an organic, electro-optical element according to one of the abovementioned embodiments. For this purpose, the method comprises the steps:
coating at least one side of a substrate with an antireflection coating, and
applying at least one electro-optical structure, which comprises at least one organic, electro-optical material, where the substrate is coated with an antireflection coating which has at least one layer with a thickness and a refractive index for which the integral reflectivity at the boundary faces of the antireflection coating for light beams emerging for all angles in the active layer and for a wavelength in the spectral range of the emitted light of the electro-optical material is minimal or for which the integral reflectivity is at most 25 percent higher than the minimum.

According to one embodiment of the method according to the invention, the coating thickness and the refractive index of the antireflection coating are selected here in accordance with a minimization of the above equations 1), 7) or 8) in conjunction with the equations 2) to 5).

In order to coat with the antireflection coating it is suitable to use all known coating deposition methods such as vacuum coating methods, in particular physical vapor deposition (PVD) or sputtering, chemical deposition methods from the gas phase (CVD) which can be carried out in a thermally enhanced fashion or plasma enhanced fashion (PECVD) or pulsed fashion (for example PICVD), or coatings from the liquid phase such as sol-gel coating, immersion coating, spray coating or centrifugal coating.

A development of the method according to the invention in which the step of coating at least one side of a substrate with an antireflection coating comprises the step of immersion coating of the substrate is particularly cost-effective and advantageous for manufacturing electro-optical elements over a large area. Immersion coating allows scratch-resistant and weather-resistant layers to be manufactured with versatile optical properties in an efficient and cost-effective fashion.

It is particularly advantageous if the antireflection coating of the substrate has titanium oxide. Titanium oxide has a high refractive index and can be easily applied as a coating component to the substrate by means of immersion coating. By selecting the titanium oxide content it is also possible to set the desired refractive index of the antireflection coating, or of one of the antireflection coating layers during the manufacture.

The step of applying at least one electro-optical structure also preferably comprises the steps:
applying a first conductive layer,
applying an active layer which comprises the at least one organic, electro-optical material, and
applying a second conductive layer.

In order to obtain particularly effective, repeatedly antireflected surfaces or boundary faces it is advantageous if the at least one antireflection coating has a plurality of layers, or if the step of coating at least one side of a substrate with an antireflection coating comprises the step of coating with an antireflection coating which has a plurality of layers. It is particularly favorable in this context if the layers each have different refractive indices.

Antireflection coatings which have three layers are particularly favorable. The back reflection into the substrate can be very effectively suppressed if the layers are arranged starting from the substrate in a layer sequence of a layer with a medium refractive index/layer with a high refractive index/layer with a low refractive index. The step of coating with an antireflection coating which has a plurality of layers, in particular three layers, can accordingly advantageously comprise the steps:
applying a layer with a medium refractive index,
applying a layer with a high refractive index and
applying a layer with a low refractive index.

Instead of a three-layer antireflection coating which corresponds to triple antireflection it is also possible to include layers of the electro-optical structure itself in the antireflection coating. For example, an ITO layer of the electro-optical structure can be adjacent to a two-layer antireflection coating in order to form in turn a three-layer antireflection coating together with these two layers with correspondingly matched refractive indices. Accordingly, in such an embodiment the antireflection coating has at least two layers, one of the conductive layers of the electro-optical structure being adjacent to the antireflection coating.

The at least one antireflection coating and the at least one electro-optical structure can advantageously be applied to the same side of the substrate. As a result, an electro-optical element is provided in which reflections are reduced as the light passes at the boundary face between the substrate and electro-optical structure. Furthermore, at least one adaptation coating can be applied to the antireflection coating applied in this way, before the application of the layers for the electro-optical structure in order to bring about optical adaptation to the refractive indices of the electro-optical structure.

The at least one antireflection coating and the at least one electro-optical structure can, however, also be applied on opposite sides of the substrate. In an electro-optical element which is manufactured in this way and in which the antireflection coating is located on the side of the substrate which lies opposite the side on which the at least one electro-optical structure is applied, reflection suppression is provided on the viewing side or light exiting side.

If an antireflection coating according to the invention is arranged on the side on which the electro-optical structure is located, it may also be advantageous if at least one adaptation coating is arranged between the antireflection coating and the electro-optical structure. The at least one adaptation coating, advantageously also an adaptation coating stack or a multi-layer adaptation coating, can advantageously serve to match the optical properties of the antireflection coating and of the electro-optical structure better to one another.

In particular it is possible also to apply antireflection coatings to both sides of the substrate. If both sides of the substrate have antireflection coatings according to the invention, the extraction and/or inputting of light out of and into the element are extensively improved.

The organic, electro-optical elements, in particular also OLEDs, according to the invention can also easily be manufactured by already using, during the manufacture, for example, an antireflected substrate with at least one antireflection coating according to the invention which has a coating thickness and refractive index which are optimized or improved according to the invention with respect to the integral reflectivity. It is particularly suitable for this to use, inter alia, AMIRAN glass as a substrate in the form in which it is already used over large areas, for example for low-reflection window glass, with correspondingly adapted layer thicknesses of the layers of the antireflection coatings. The at least one antireflection coating can therefore advantageously comprise an AMIRAN coating, the layer thicknesses of the antireflection coating being able to be adapted according to the invention, or an additional antireflection coating which is embodied according to the invention being applied.

According to a further embodiment of the invention, an organic, electro-optical element comprises at least one electro-optical structure with an active layer with organic, electro-optical material, an antireflection coating being arranged between the substrate and electro-optical structure, and light-scattering structures being present between the electro-optical structure and the substrate. The light-scattering structures bring about in a surprisingly simple way both a layer which is optimized in terms of its thickness and refractive index and a significant increase in the extraction efficiency and input efficiency compared to known OLEDs elements.

An antireflected glass substrate can generally be used with an antireflection coating with light-scattering structures as a carrier both for an organic, electro-optical element such as, in particular, an organic, light-emitting diode, and for other light-emitting elements such as semiconductor diodes or anorganic electroluminescent elements.

According to one embodiment of the invention, the light-scattering structures may be present in the antireflection coating. This can easily be implemented by, for example, applying an antireflection coating which contains light-scattering structures, for example in the form of crystals, particles or occlusions, which have a refractive index which differs from the surrounding material and/or a differing orientation.

According to a further embodiment of the invention, there is provision to apply an additional layer which has light-scattering structures for increasing the extraction efficiency. This layer can be arranged, for example, between the substrate and electro-optical structure. In an advantageous development, the additional layer is arranged on the substrate or in contact with the substrate, for example it is applied to it and has a refractive index which corresponds essentially to the refractive index of the substrate. In this way, no reflections which reduce the extraction efficiency occur at the boundary face between this layer and the substrate.

According to yet another embodiment, a structured boundary face between the substrate and antireflection coating has light-scattering structures. Such an arrangement can be manufactured by applying the antireflection coating to a structured side of the substrate. In the simplest case it is possible for this purpose to roughen the substrate surface on the side provided for the antireflection coating. According to one development of the invention, the substrate surface can also be provided with regular structures and the antireflection coating can be applied to the side of the substrate.

Better quanta yields can also be achieved if, in addition to the active layer, further functional layers are also arranged between the first and second conductive layers. For example a hole injection layer and/or a potential adaptation coating and/or an electrode blocking layer and/or a hole blocking layer and/or a hole conductive layer and/or electron conductive layer and/or an electron injection layer for the quantum efficiency of the organic, electro-optical structure, are advantageous as further functional layers, these layers, like the active layers, being arranged between the first and second conductive layers.

In order to achieve high internal quantum efficiencies it is favorable if the layers are applied or arranged in the sequence hole injection layer/potential adaptation coating/hole conductive layer/electron blocking layer/active layer/hole blocking layer/electron conductive layer/electron injection layer. It is also possible to use parts, combinations or multiple uses of these functional layers which are known to the person skilled in the art.

The invention will be described in more detail below with reference to preferred embodiments and to the appended figures. Here, identical reference symbols designate identical or similar parts.

In the drawings:

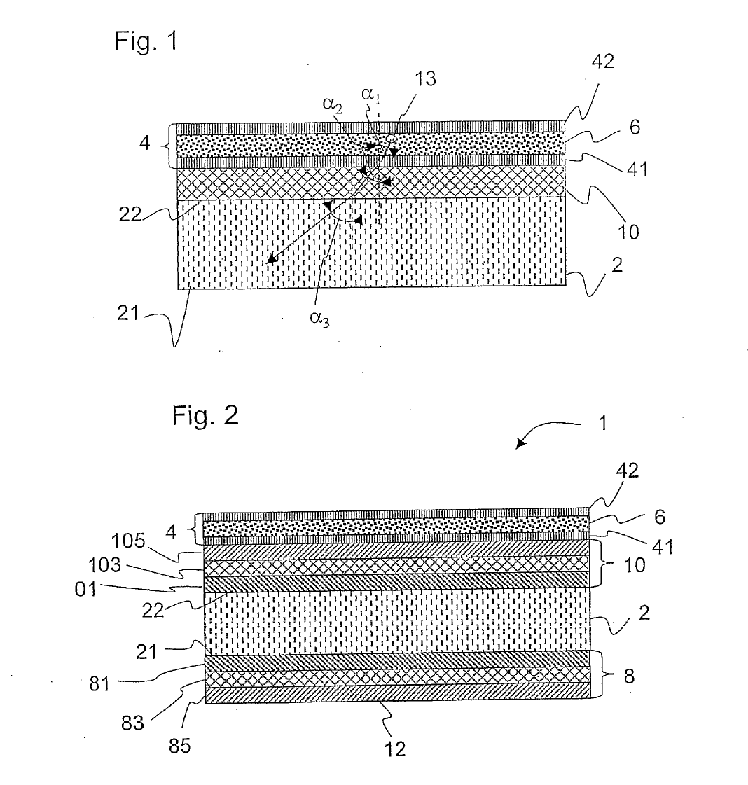

FIGS. 1 to 4 show schematic cross sections through embodiments of organic, electro-optical elements according to the invention,

FIG. 5 shows a calculation of the integral reflectivity of an antireflection coating for various values of the coating thickness and of the refractive index of the antireflection coating,

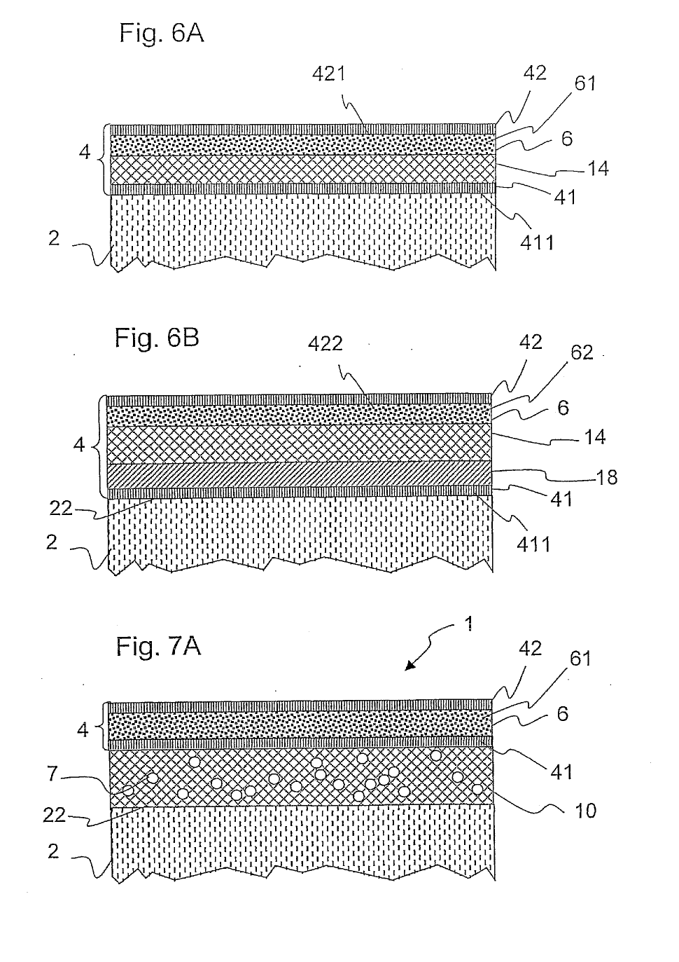

FIGS. 6A and 6B show embodiments of electro-optical structures of an organic, electro-optical element,

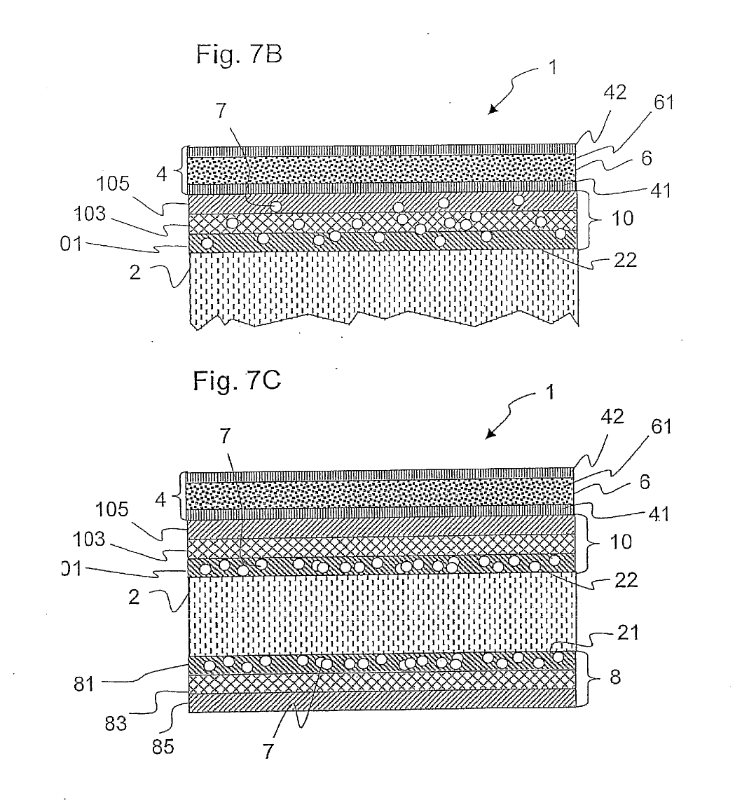

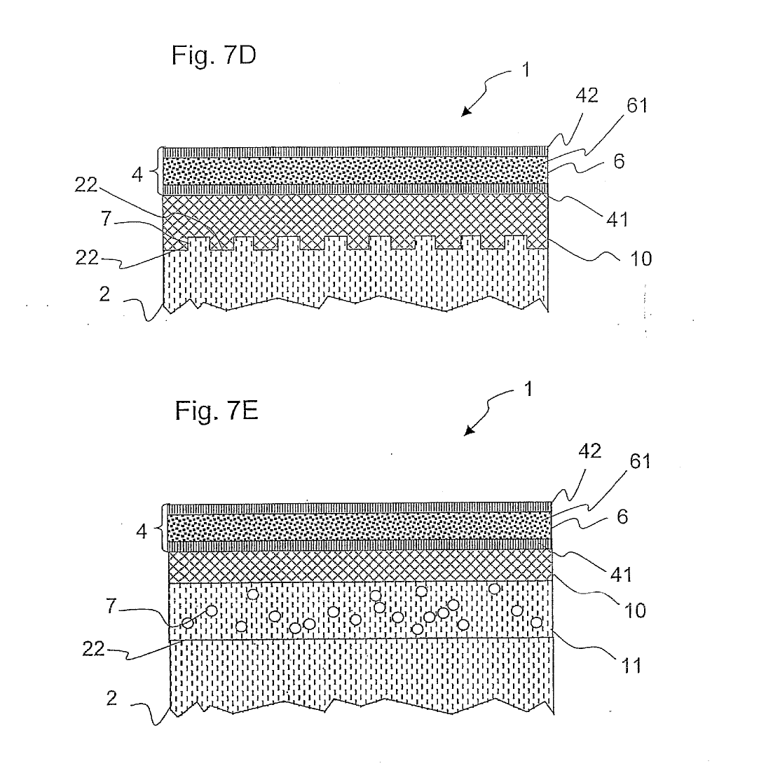

FIGS. 7A to 7E show exemplary embodiments of antireflection coatings with light-scattering structures,

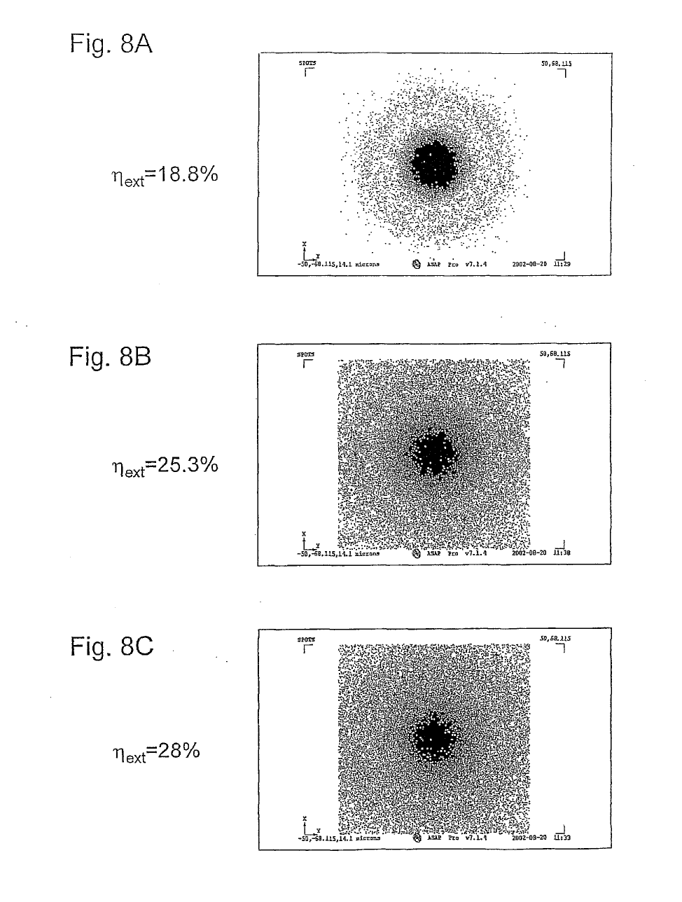

FIGS. 8A to 8C show raytracing simulations for various layer arrangements,

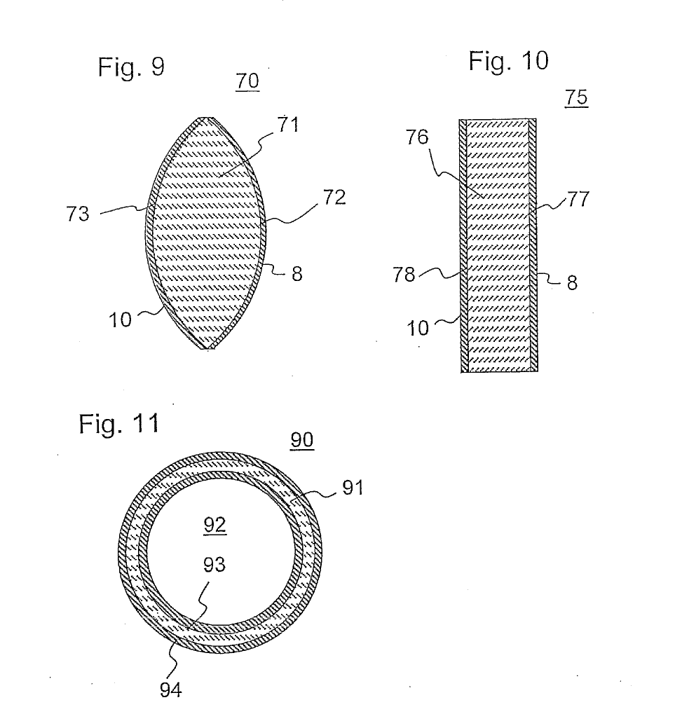

FIGS. 9 to 11 show various further optical devices with antireflection coatings according to the invention.

FIG. 1 shows a cross section through a first embodiment of an electro-optical element according to the invention which is designated in its entirety by 1. A transparent, flat or plate-shaped substrate 2 serves as the carrier of the element 1, preferably glass and/or plastic being used as the substrate material. For example substrate thicknesses in the range from 10 to 2000 micrometers, preferably in the range from 50 to 700 micrometers, are suitable.

In this embodiment, an electro-optical structure 4 is arranged on the side 22 of the substrate 2. The electro-optical structure 4 comprises here a first conductive layer 41 and a second conductive layer 42, between which an active layer 6 is arranged. The active layer 6 contains here organic, electro-optical material.

An antireflection coating 10 which reduces reflections between the conductive layer 41 facing the substrate 2 and the surface of the substrate 2 is also arranged between the substrate 2 and the electro-optical structure 4.

The refractive index of the antireflection coating 10 is preferably selected such that it is between the refractive indices of the adjacent layers. In customary simple, single-layer antireflection coatings or refractive index adaptation coatings, the thickness of said coatings is generally selected such that it corresponds to a quarter of the wavelength of the exiting light. Furthermore, in accordance with the teaching which is known from the prior art for the refractive index of the antireflection coating the geographic mean of the two refractive index values of the media which are adjacent to the antireflection coating are postulated as the optimum.

If, for example, glass with a refractive index of n₃=1.53 (given 550 nm wavelength) is used as the substrate 2 and indium-tin oxide is used as the transparent conductive layer 41 of the electro-optical structure 4 with a refractive index of n₁=1.85 (given a 550 nm wavelength), a refractive index of n₂=(1.85·1.53)^{1/2}=1.68 and a thickness of 81.7 nm which is optimized for a wavelength of 550 nanometers occur for an antireflection coating constructed in accordance with the known technical teaching.

In contrast to this, a single-layer antireflection coating of an electro-optical element 1 according to the invention in which the integral reflectivity at the boundary faces of the antireflection coating for all the light beams emerging for all angles in the active layer is minimal, has a refractive index and a coating thickness which deviates completely from these values. An antireflection coating which is optimized according to the invention with respect to the integral reflectivity has, given the same refractive indices of n₁=1.85 and n₃=1.53, a refractive index of n₂=1.59 (in each case given a 550 nm wavelength) and a much larger layer thickness of 260 nanometers.

Since a layer with a precisely defined refractive index and precise coating thickness cannot always be implemented without difficulties in an industrial production process, the values for the refractive index and coating thickness of the coating 10 can, however, also deviate from one another to such an extent that the integral reflectivity resulting from these values is at most 25 percent, preferably at most 15 percent, particularly preferably at most 5 percent, higher than the theoretically achievable minimum of the integral reflectivity.

The values for the refractive index and coating thickness of an antireflection coating for an element 1 according to the invention can be determined, for example, by numerical calculation of the integral reflectivities specified above in equation 1) for in each case a set of values for the refractive index and coating thickness and determination of the minimum value of the integral reflectivities calculated in this way.

In addition, for the sake of better understanding of the parameters in the above equations 1) to 5) in FIG. 1, an imaginary emitter 13 is shown in the active layer 6 and a light beam 10 which emerges from this emitter.

If the integral reflectivity of the antireflection coating 10 of the embodiment shown in FIG. 1 is determined according to the equation 1), the angle α₁ designates the angle measured with respect to the perpendicular to the boundary face between the layer 41 and the antireflection coating 10, of the light beam which travels through the layer 41. The angle α₂ is the angle which is measured with respect to the perpendicular to the boundary face, of the light beam which is refracted at the boundary face between the layer 41 with the refractive index n₁ and the antireflection coating with the refractive index n₂ and travels in the antireflection coating. The angle α₃ is also the angle of the light beam which travels in the substrate 2 and is refracted at the opposite boundary face of the antireflection coating 10 with respect to the substrate 2 with the refractive index n₃.

A large number of organic, electroluminescent materials do not have any clearly defined monochromatic emission line or a narrow band emission spectrum but rather instead emit light with a spectral intensity distribution within a certain spectral region. In order, with respect to the overall brightness in this context, to achieve an increase in the overall brightness which can be extracted compared to known OLED elements, the refractive index and the layer thickness of the layer of the antireflection coating 10 can also be selected such that the reflectivity which is integrated over all the angles of the light beams emerging from the active layer 6 and the wavelength of the spectral range of the emitted radiation, and which is weighted with the spectral intensity distribution, at the boundary faces of the antireflection coating 10 is minimal, or at most 25 percent, preferably 15 percent, particularly preferably 5 percent, higher than the minimum of the weighted and integrated reflectivity. This integral can be calculated according to equation 7) and the values of the refractive index and the layer thickness can be determined for the minimum achievable value of the integral.

An additional improvement can also be achieved if a thickness and a refractive index are selected for the antireflection coating 10 layer for which the reflectivity which is integrated over all the angles of the light beam emerging from the active layer, and the wavelengths of the spectral region of the emitted radiation, and is weighted with the spectral intensity distribution and additionally the spectral sensitivity of the eyes, at the boundary faces of the antireflection coating 10 is minimal, or at most 25 percent, preferably 15 percent, particularly preferably 5 percent, higher than the minimum. The calculation of the integral can be carried out according to the above equation 8). Since the sensitivity of the eyes is additionally taken into account, for the viewer an even better result in subjective terms is achieved with respect to the brightness of the OLED element 1. The values of the refractive index and layer thickness of the minimum values of the integrals of the reflectivities which are weighted with the spectral intensity distribution, or additionally with the sensitivity of the eyes, generally also corresponds to the minimum value of the integral reflectivity for an individual wavelength in the spectral region of the emitted radiation according to equation 1), even if the emitted light is not monochromatic. However, the minimum value of the integral reflectivity according to equation 1) may then be at a wavelength at which the emitted intensity is not at a maximum.

FIG. 2 illustrates a cross section through a further embodiment of an organic, electro-optical element 1 according to the invention. In this embodiment, a first antireflection coating 8 is applied to the substrate 2 on a first side 21, and a second antireflection coating 10 is applied on a second side 22.

The antireflection coatings each comprise three layers 81, 83, 85, or 101, 103 and 105. The antireflection coating layers have refractive indices which are different from one another. Specifically, the layers are arranged in such a way that, starting from the substrate, they are arranged in a layer sequence of a layer with a medium refractive index/layer with a high refractive index/layer with a low refractive index. Correspondingly, the layers 83 and 103 have a higher refractive index than the layers 81 and 101, and the layers 85 and 105, the layers 85 and 105 each having the lowest refractive indices of the antireflection coatings 8 and 10.

The refractive index and the layer thickness of each of the layers 81, 83, 85 and 101, 103 and 105 of the two antireflection coatings 8 and 10 are selected here in such a way that the integral reflectivities of the antireflection coatings 8, 10 are each minimal or deviate from the minimum by 25% at most.

An electro-optical structure 4 with an active layer 6 is applied to the antireflection coating 10 on the side 22 of the substrate 2, said electro-optical structure 4 comprising an organic electro-optical material. The antireflection coating 8 is arranged on the side 21 of the substrate 2 which lies opposite the side 22 on which the electro-optical structure 4 is applied.

The electro-optical structure 4 comprises, as in the embodiment shown in FIG. 1, a first conductive layer 41 and second conductive layer 42, between which an active layer 6, which contains the organic, electro-optical material, is arranged.

In the case of an organic, electro-optical element which is constructed as an OLED, light, which is generated by the organic electro-optical material through electroluminescence or electron/hole recombination, is directed outwards through the first conductive layer 41 via the substrate 2, emerging on the light exit side and/or light input side 12 of the element 1. In order to permit light to pass through the first conductive layer 41, the conductive first layer 41 of the electro-optical structure is manufactured, for example, from partially transparent, conductive material such as, for example, indium-tin oxide (ITO), a transparent conductive oxide (TCO) or a thin metal layer.

In the case of a photovoltaic element in which light forms electron-hole pairs in the organic, electro-optical material in the active layer 6, the beam path is correspondingly reversed.

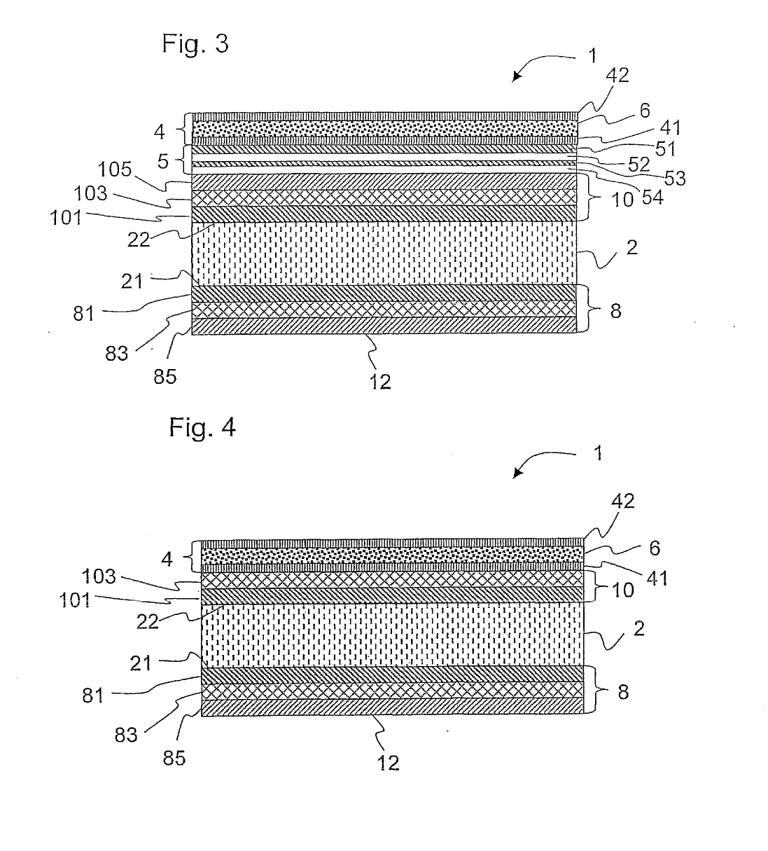

FIG. 3 illustrates a cross section through a further embodiment of an organic electro-optical element 1 according to the invention. This embodiment differs from the embodiment illustrated in FIG. 2 in having an additional adaptation coating 5 between the electro-optical structure 4 and the antireflection coating 10. The adaptation coating 5 serves to adapt better the refractive index between the antireflection coating 10 and the conductive layer 41 of the electro-optical structure 4. The adaptation coating can also be of multilayer design, as shown in FIG. 3, in which case the adaptation coating 5 which is then shown by way of example comprises the four layers 51, 52, 53 and 54.

The adaptation coatings are favorable in particular if electro-optical structures which have different designs are to be combined with a substrate with prefabricated antireflection. In this way it is possible to use a defined type of substrate without changes for a plurality of different electro-optical structures. For example, in this way the AMIRAN substrates which were originally intended for other applications can be used.

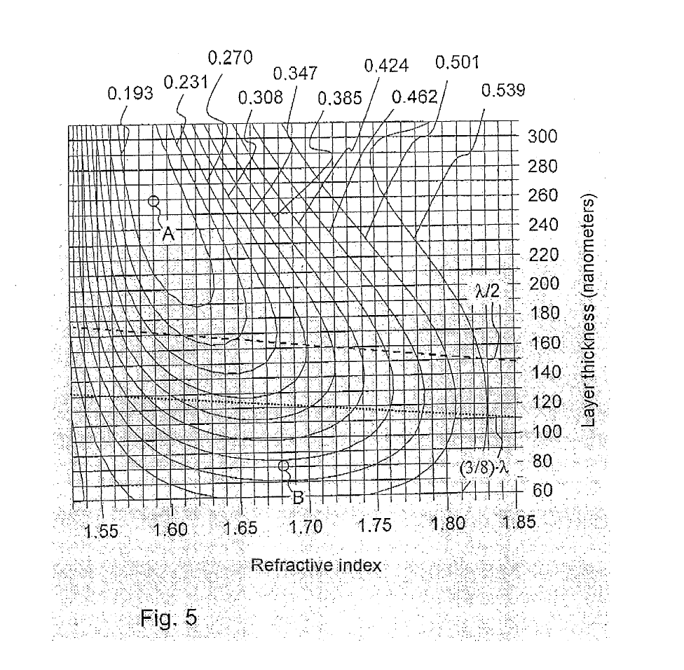

FIG. 4 shows yet a further embodiment of the organic, electro-optical element 1 according to the invention. In this embodiment, the antireflection coating 10 comprises two layers 101 and 103. Compared to the previous embodiments, the antireflection coating 10 of this embodiment which adjoins the conductive layer 41 accordingly does not have a third layer 105. Instead, the conductive layer 41 itself performs the function of a third layer of a three-layer antireflection coating.

This can be achieved easily, for example, by selecting the refractive indices for the layers 101 and 103 of the antireflection coating 10 in the scope of an antireflection coating which is improved according to the invention with respect to the integral reflectivity in such a way that the refractive index of the conductive layer 41 of the electro-optical structure 4 is less than the refractive indices of the layers 101 and 103. In this embodiment the layer 103 also preferably has the highest refractive index of the layers.

For the multi-layer antireflection coatings 8, 10, like those which are shown in FIGS. 2 to 4, the same also applies as for the single-layer antireflection coating of the exemplary embodiment shown in FIG. 1, namely that the layers of the antireflection coating 8, 10 have a thickness and a refractive index for which the integral reflectivity at the boundary faces of the antireflection coating 10 for all light beams emerging for all angles in the active layer is minimal for a wavelength in the emitted spectral region, or for which the integral reflectivity is higher than the minimum by at most 25 percent.

In order to determine layer thicknesses and refractive indices of the layers of a multi-layer coating which are improved in this way, the integral reflectivity can be calculated numerically in accordance with the above equations 1), 7) or 8) of the entire, multi-layer antireflection coating 8, or 10, by recursive application of the equations 2) to 5) for the individual layers 81, 83, 85 and 101, 103, 105 of the antireflection coatings.

In the embodiments of organic, electro-optical elements which are illustrated with reference to FIGS. 2 to 4, one or more layers of the antireflection coating 10 can also have light-scattering structures.

FIG. 5 shows graphs of the integral reflectivity of a single-layer antireflection coating, such as the exemplary embodiment in FIG. 1 has, as a function of the refractive index and coating thickness of the antireflection coating 10. For the conductive, transparent electrode layer 41 which is adjacent to the antireflection coating 10, a refractive index of n=1.85 is assumed. A glass with a refractive index of n₃=1.45 is used as the substrate 2 for the basis of the calculation. Various discrete values of the integral reflectivity in the range from 0.193 to 0.539 are illustrated as curves in FIG. 5.

The minimum reflectivity of 0.154 for a single-layer antireflection coating with boundary faces with media with n₁=1.85 and n₃=1.45 is obtained at point A. This point is located at the values n₂=1.59 and d=260 nanometers.

The curve with an integral reflectivity of 0.193 also bounds the value range of the refractive index and coating thickness of the antireflection coating in which the integral reflectivity is at most 25% higher than the minimum value of 0.154.

The point B designates the values for the refractive index and coating thickness of an antireflection coating which is optimized in the conventional way for identical adjacent media for perpendicular exiting of light as a quarter-wavelength layer. For such a quarter-wavelength layer, values of n₂=1.68 and d=81.7 nanometers which differ significantly from an antireflection coating according to the invention are obtained. An antireflection coating according to the invention therefore surprisingly has a significantly higher coating thickness and a significantly lower refractive index for the described configuration compared to a customary quarter-wavelength layer.

In particular, in the case of antireflection coatings according to the invention such as those described above for electro-optical elements, or else applications such as optical elements, for example lenses, filters, prisms, panes, in particular window panes, car glass, architecture glass, or lighting bodies, the antireflection coating layer has an optical thickness of at least ⅜ of a wavelength of the transmission spectrum or emission spectrum, preferably even at least one half wavelength.

In the example shown in FIG. 5, the range of at least one half wavelength of optical thickness is above approximately 163 nanometers layer thickness. The lower limit of this range is indicated in FIG. 5 by a dashed line, designated by “λ/2”, and the lower limit of the range of an optical thickness of at least ⅜ of the wavelength is indicated by a dotted line which is designated by “(⅜)·λ”.

FIGS. 6A and 6B show cross sections through various exemplary embodiments of electro-optical structures 4. The substrate 2, on which the electro-optical structure 4 is applied, is illustrated in each case without an antireflection coating for the sake of clarity.

In the first embodiment of an electro-optical structure 4 which is shown in FIG. 6A, the first conductive layer 41 has an indium-tin oxide layer 411 which is in contact with the substrate 2 or with an antireflection coating (not illustrated) on the substrate 2.

A hole injection layer 4 is applied to the indium-tin oxide layer 411. Said layer 14 can comprise, for example, a polymer layer which contains, for example, polyanilline or PEDOT/PSS (“poly(3,4-ethylene-dioxythiophene)/poly(styrenesulfonate)”).

An active, electroluminescent layer 6 is applied to this hole injection layer 14 and comprises a polymer layer composed of MEH-PPV 61 as organic electro-optical material. Here, MEH-PPV designates the polymer (poly(2-methoxy, 5-(29-ethyl-hexyloxy)-1,4-phenylenevinylene)).

The second conductive layer 42 which is applied to the active layer 6 comprises a calcium-aluminum 2-layer system 421 in this embodiment.

The principle layer sequence ITO layer/PEDOT/PSS layer/MEH-PPV layer/Ca/Al layer of this embodiment has proven suitable, inter alia, for use as an OLED, in which case on an individual basis it has already been possible to obtain significantly above 10 000 operating hours with such a layer structure.

FIG. 6B shows a further, exemplary embodiment of an electro-optical structure 4. The latter has an additional hole transport layer 18 which is applied after the hole injection layer 14. For example, N,N′-diephenyl-N,N′-bis(3-methylphenyl)-1,1′-biphenyl-4,4′-diamine (TPD) is suitable as the material for a hole transport layer 18. N,N′-bis(1-naphthyl)-N,N′-diphenyl 1-1,1-biphenyl 1-4,4′-diamines (NPB) is also suitable for this purpose.

The active, electroluminescent layer 6 comprises, in this embodiment, a layer 62 as an organic, electro-optical material which has Alq₃ (tris(8-quinolinolato) aluminum). However, organic molecules with a low mass number (“small molecules”) which can, for example, be vapor-deposited by means of PVD, and organic electroluminescent polymers can also be used as organic electroluminescent materials.

The conductive layer 42 of this embodiment comprises a layer 422 composed of a magnesium-silver alloy with a low ionization energy level.

In addition to the embodiments illustrated with reference to FIGS. 6A and 6B, a large number of further suitable electro-optical structures are known which are suitable for OLEDs or corresponding photovoltaic elements and can be used for the present invention. Thus, inter alia, a large number of organic, electroluminescent materials, conductive electrode layers as well as, in addition to the abovementioned hole transport and hole injection layers also a large number of further functional layers have become known which increase the efficiency of OLEDs or photovoltaic elements.

Such layers and materials as well as various possible layer sequences within organic, electro-optical elements such as, in particular of OLEDs, are described, for example, in the following documents as well as the literature references therein, which are incorporated fully in the present application in this respective by reference:
1. Nature, vol. 405, pages 661-664,
2. Adv. Mater. 2000, 12, No. 4, pages 265-269,
3. EP 0573549,
4. U.S. Pat. No. 6,107,452.

FIGS. 7A to 7E show embodiments of the invention in which the antireflection coating 10 also has light-scattering structures 7 which scatter at least part of the light passing through the coating 10 and thus deflect a portion of the light, which would otherwise be incident on one of the boundary faces of the coating 10 at a total reflection angle, said deflection occurring in such a way that its angle of incidence is below the critical angle and it can pass through the boundary face. As a result, the extraction efficiency or input efficiency is increased further. The light-scattering structures can be present here both in the interior of the coating 10 and at one boundary face or at both boundary faces of the coating 10.

FIG. 7A shows an exemplary embodiment of an organic, electro-optical element 1 with a single-layer antireflection coating 10. The basic design of this element 1 according to the invention corresponds here to the embodiment shown with reference to FIG. 1. The electro-optical structure 4 is illustrated in simplified form with a three-layer structure, but it can also be structured, for example, in accordance with FIGS. 6A and 6B.

In the exemplary embodiment shown in FIG. 7A, the antireflection coating 10 which is arranged between the electro-optical structure 4 and the substrate 2 has light-scattering structures 7 in the form of small crystals, particles or occlusions which at least partially scatter the light passing through the coating 10. The particles or occlusions have, for this purpose, for example a different refractive index than the rest of the coating 10 or the material surrounding the particles. The size of the particles is of the same order of magnitude as, or smaller than, the light wavelength to which the antireflection coating 10 is adapted. Particularly effective scattering of the light is achieved by particles or occlusions of this size.

FIG. 7B shows an embodiment of the invention with a three-layer antireflection coating 10 such as the exemplary embodiments in FIG. 2 to FIG. 4 also have, for example. The light-scattering structures are present in each of the layers 101, 103, 105 of the antireflection coating in this embodiment.

FIG. 7C also shows an exemplary embodiment with a three-layer antireflection coating. Here, as in the exemplary embodiments in FIG. 2 to FIG. 4, in each case a three-layer antireflection coating 10 or 8 is arranged both on the side 22 of the substrate 10 and on the opposite side 21. In the exemplary embodiment shown in FIG. 7C, the light-scattering structures are located in the layers 81 and 101 which are applied first to the substrate 2. Of course, the light-scattering structures can, however, also be arranged in a different layer or in two layers of the antireflection coatings 8, 10.

FIG. 7D shows yet a further exemplary embodiment with an antireflection coating 10 with light-scattering structures 7. In contrast to the exemplary embodiments illustrated in FIGS. 7A to 7C, the boundary face between the substrate and antireflection coating 10 is structured. For this purpose, the antireflection coating is applied to the structured side 21 of the substrate so that the antireflection coating has light-scattering structures 7 at its boundary face with the substrate 2.

In the embodiment shown in FIG. 7D, the antireflection coating is applied in particular to the side 22 of the substrate 2 which is provided with regular structures in the form of regular projections, so that correspondingly regular, light-scattering structures 7 are produced at the boundary face. In contrast to what is shown in FIG. 7D, the face 22 can, however, also simply be roughened with a suitable method, for example by etching, so that the light-scattering structures are irregular.

As is shown by FIG. 7E, the light-scattering structures can, however, also be applied in an additional layer 11 on the side 22 of the substrate 2. The refractive index of the matrix of this layer 11 which is arranged on the substrate 2 can advantageously be selected such that it corresponds as well as possible to the refractive index of the substrate 2. In this case, the layer does not have a refractive, and thus reflective, effect at the boundary face with the substrate if it is in contact with the substrate but rather only a scattering effect, and is not a component of the antireflection coating.

FIGS. 8A to 8C show raytracing simulations for various layer arrangements of organic, electro-optical elements. The graphs of FIGS. 8A to 8C each show the viewing side of an organic, electro-optical element 1. Each point on the graphs represents in each case an emerged light beam, a dot-shaped radiation source in the active layer of an OLED being used as an electro-optical structure serving as the basis for the calculation. The radiation source is located here in the center of the two-dimensional graphs. For the material of the active layer a refractive index of n=1.7 was assumed, for the transparent, conductive electrode layer arranged between the active layer and the substrate a refractive index of n=1.85 was assumed, and for the substrate a refractive index of n=1.45 was assumed. The refractive index of n=1.85 of the conductive electrode layer corresponds here to the refractive index of indium-tin oxide.

FIG. 8A shows the calculation for an arrangement without an antireflection coating between the OLED and substrate. Such an arrangement, such as is conventionally used in OLED elements, shows an external efficiency of only 18.8%.

FIG. 8B shows the result of a simulation for an arrangement according to the invention such as that illustrated in FIG. 1, but without light-scattering structures. n=1.65 was assumed for the refractive index of the antireflection coating. The thickness of the antireflection coating is d=0.15 μm. With such an arrangement corresponding to the exemplary embodiment illustrated in FIG. 1 without light-scattering structures an increase in the external quantum efficiency to 25.3% is achieved.

Finally, FIG. 8C shows a simulation for an embodiment according to the invention as shown in FIG. 8, with additional light-scattering structures corresponding to the embodiment illustrated in FIG. 7A. Layer thicknesses and refractive indices correspond here to the simulations used as the basis of FIG. 8B. The external quantum efficiency increases here to 28% as a result of the introduction of the light-scattering structures.

In FIGS. 9 to 11, further examples of optical devices with antireflection coatings according to the invention are illustrated. FIG. 9 shows an example of an optical component, with antireflection coating according to the invention, in the form of a lens 70 which is shown in cross section. The lens can be, for example, a spectacle glass or a lens of an objective.

Both refractive faces 72, 73 of the substrate 71 of the lens 70 are coated here with antireflection coatings 8 or 10 according to the invention, said coatings being formed in the same way as the antireflection coatings of the electro-optical elements according to the examples described above.

Instead of the wavelength of the spectrum emitted by the functional layers of the optical element it is possible here to optimize the thicknesses and refractive indices to a wavelength of the visible spectrum, preferably the central wavelength of the visible spectrum. In particular, each of the antireflection coatings 8, 10 can also again have an optical thickness which is at least ⅜, preferably at least ½ times the wavelength from the spectrum.

FIG. 10 shows a further example of an optical component, here an optical filter 75 in cross section. Here too, the entry face 77 and exit face 78 of the transparent substrate 76 are each provided with antireflection coatings 8 or 10 according to the invention. For an optical filter it is appropriate to adapt the layer thickness of the at least one antireflection coating layer to the smallest possible integral reflectivity for a wavelength of the filtered spectrum. For example, the antireflection coating can be optimized to the central wavelength of the filtered spectrum which is weighted with the intensity distribution. The substrate 76 can also be, for example, a pane, for example a window, in particular also architecture glass, a window for aircraft, ships or vehicles. It is appropriate here to use a layer thickness of the at least one antireflection coating layer which is optimized in terms of its integral reflectivity for the central wavelength of the optical spectrum, or the central wavelength of the optical spectrum which is weighted with the intensity distribution of the daylight spectrum and/or the spectral sensitivity of the eyes.

FIG. 11 illustrates an example of a lighting element which is equipped with antireflection coatings according to the invention. The lighting element is in this example a fluorescent tube 90 with a tubular glass substrate 91 which surrounds a glass discharge space 92. Both the inner face 93 and the outer face of the substrate are equipped with antireflection coatings 8, 10 which are optimized according to the invention to minimum, integral reflectivity, for example for the weighted average of the fluorescence spectrum.

It is clear to a person skilled in the art that the invention is not restricted to the embodiments described above but rather can be modified in a variety of ways. In particular, the features of the individual exemplary embodiments can also be combined with one another.

### LIST OF REFERENCE NUMBERS

1 Organic, electro-optical element
2 Substrate
4 Electro-optical structure
Adaptation coating
6 Active layer of the electro-optical structure 4
7 Light-scattering structure
8, 10 Antireflection coatings
11 Layer with light-scattering structures 7
12 Light exit side and/or light entry side
13 Imaginary emitter
14 Hole injection layer (PEDOT/PSS, CuPC)
18 Hole conductor layer (TPD, TDAPB)
21 First side of the substrate 2
22 Second side of the substrate 2
41 First conductive layer of the electro-optical structure 4
42 Second conductive layer of the electro-optical structure 4
51-54 Layers of the adaptation coating
61 MEH-PPV layer
62 Alq₃ layer
70 Lens
71 Substrate of 70
72, 73 Refractive faces of 70
75 Optical filter
76 Substrate of 75
77, 78 Entry faces and exit faces of 75
81, 83, 85 Layers of the antireflection coating 8
90 Fluorescent tube
91 Substrate of 90
92 Gas discharge space of 90
93 Internal face of 91
94 External face of 91
101,103,105 Layers of the antireflection coating 10
411 Indium-tin oxide layer
421 Ca/Al layer
422 Mg:Ag layer

1. An electro-optical element (1) comprising a substrate (2) and at least one electro-optical structure (4) which comprises an active layer with at least one organic, electro-optical material (61), the substrate having at least one antireflection coating (8, 10) with at least one layer, wherein the antireflection coating (8, 10) layer has a thickness and a refractive index for which the integral reflectivity at the boundary faces of the antireflection coating is one of: (i) minimal for light beams emerging from the active layer at all angles for a wavelength in the spectral region of the emission spectrum, and (ii) at most 25% higher than the minimum, the integral reflectivity being the reflectivity which is integrated over all the emission angles of light beams which emerge from the active layer, at the boundary faces of the antireflection coating.

2. The element as claimed in claim 1, wherein the thickness of the coating and the refractive index of the antireflection coating are selected such that the integral of the reflectivity of the antireflection coating
$$I ( {n}_{1} , {n}_{2} , {n}_{3} , d ) = {\int }_{0}^{π / 2} R ( {n}_{1} , {n}_{2} , {n}_{3} , d , θ ) sin ( θ ) ⅆ θ \qquad 1 )$$
is one of (i) minimal and (ii) deviates from the minimum value by 25% at most, n₂ designating the refractive index of the antireflection coating (10), n₁ and n₃ designating the refractive indices of the media which adjoin the antireflection coating (10), θ designating the angle of the emitted light with respect to the perpendicular to the boundary face of the antireflection coating facing the emitter, and d designating the coating thickness of the antireflection coating, and the following being stipulated for the reflectivity R(n₁, n₂, n₃, d, θ):
$$\begin{matrix}R ( {n}_{1} , {n}_{2} , {n}_{3} , d , θ ) = \frac{{R}_{TE} + {R}_{TM}}{2} , where & 2 ) \\ {R}_{TE} = \frac{{r}_{12}^{2} + {r}_{23}^{2} + 2 {r}_{12} {r}_{23} cos ( 2 β )}{1 + {r}_{12}^{2} {r}_{23}^{2} + 2 {r}_{12} {r}_{23} cos ( 2 β )} , where & 3 ) \\ {r}_{12} = \frac{{n}_{1} cos ( {α}_{1} ) - {n}_{2} cos ( {α}_{2} )}{{n}_{1} cos ( {α}_{1} ) + {n}_{2} cos ( {α}_{2} )} , and & 3 a ) \\ {r}_{23} = \frac{{n}_{2} cos ( {α}_{2} ) - {n}_{3} cos ( {α}_{3} )}{{n}_{2} cos ( {α}_{2} ) + {n}_{3} cos ( {α}_{3} )} , or & 3 b ) \\ {R}_{TM} = \frac{{r}_{12}^{2} + {r}_{23}^{2} + 2 {r}_{12} {r}_{23} cos ( 2 β )}{1 + {r}_{12}^{2} {r}_{23}^{2} + 2 {r}_{12} {r}_{23} cos ( 2 β )} , where & 4 ) \\ {r}_{12} = \frac{{n}_{2} cos ( {α}_{1} ) - {n}_{1} cos ( {α}_{2} )}{{n}_{2} cos ( {α}_{1} ) + {n}_{1} cos ( {α}_{2} )} , and & 4 a ) \\ {r}_{23} = \frac{{n}_{3} cos ( {α}_{2} ) - {n}_{2} cos ( {α}_{3} )}{{n}_{3} cos ( {α}_{2} ) + {n}_{2} cos ( {α}_{3} )} , and where & 4 b ) \\ β = \frac{2 π}{{λ}_{0}} {n}_{2} d cos ( {α}_{2} ) applies , and where & 5 )\end{matrix}$$
the angle α₁=θ designates the angle measured with respect to the perpendicular to the boundary face, of a light beam which is incident on the antireflection coating,
the angle α₂ designates the angle measured with respect to the perpendicular to the boundary face of the light beam which is refracted at the boundary face between the medium with the refractive index n₁ and the antireflection coating and which travels in the antireflection coating,
the angle α₃ designates the angle of the light beam which is refracted once more at the opposite boundary face with respect to the medium with the refractive index n₃ and travels in this medium, and
λ₀ designates the wavelength of the light in the vacuum.

3. The element as claimed in claim 1, wherein the antireflection coating (8, 10) layer has a thickness and a refractive index for which the reflectivity, which is integrated over all the angles of the light beams emerging from the active layer and the wavelengths of the spectral region of the emitted radiation and which is weighted with the spectral intensity distribution, at the boundary faces of the antireflection coating (8, 10), is one of (i) minimal and (ii) at most 25 percent higher than the minimum.

4. The element as claimed in claim 1, wherein the antireflection coating layer has a refractive index n₂(λ) and a thickness d, in which the integral:
$$\begin{matrix}I ( {n}_{1} ( λ ) , {n}_{2} ( λ ) , {n}_{3} ( λ ) , d ) = \\ {\int }_{{λ}_{1}}^{{λ}_{2}} {\int }_{0}^{π / 2} S ( λ ) \cdot R ( {n}_{1} ( λ ) , {n}_{2} ( λ ) , {n}_{3} ( λ ) , d , θ ) sin ( θ ) ⅆ θ ⅆ λ\end{matrix}$$
is one of (i) minimal and (ii) at most 25 percent higher than the minimum, S(λ) designating the spectral intensity distribution function, V(λ) the spectral sensitivity of the eyes, R(n₁(λ), n₂(λ), n₃(λ), d, θ) designating the reflectivity as a function of the emission angle θ, coating thickness d and the wavelength-dependent refractive index n₂(λ) of the antireflection coating and of the adjacent media, n₁(λ), n₃(λ), and λ₁ and λ₂ designating the boundaries of the emission spectrum.

5. The element as claimed in claim 1, wherein the antireflection coating (8, 10) layer has a thickness and a refractive index for which the reflectivity, which is integrated over all the angles of the light beams emerging from the active layer and the wavelengths of the spectral range of the emitted radiation and is weighted with the spectral intensity distribution and the spectral sensitivity of the eyes, at the boundary faces of the antireflection coating (8, 10) is one of (i) minimal and (ii) at most 25 percent higher than the minimum.

6. The element as claimed in claim 1, wherein the antireflection coating layer has a refractive index n₂(λ) and a thickness d, in which the integral:
$$\begin{matrix}I ( {n}_{1} ( λ ) , {n}_{2} ( λ ) , {n}_{3} ( λ ) , d ) = \\ {\int }_{{λ}_{1}}^{{λ}_{2}} {\int }_{0}^{π / 2} S ( λ ) \cdot V ( λ ) \cdot R ( {n}_{1} ( λ ) , {n}_{2} ( λ ) , {n}_{3} ( λ ) , d , θ ) sin ( θ ) ⅆ θ ⅆ λ\end{matrix}$$
is one of (i) minimal and (ii) at most 25 percent higher than the minimum, S(λ) designating the spectral intensity distribution function, V(λ) the spectral sensitivity of the eyes, R(n₁(λ), n₂(λ), n₃(λ), d, θ) designating the reflectivity as a function of the emission angle θ, coating thickness d and the wavelength-dependent refractive index n₂(λ) of the antireflection coating and of the adjacent media, n₁(λ), n₃(λ), and λ₁ and λ₂ designating the boundaries of the emission spectrum.

7. The element as claimed in claim 1, wherein the at least one electro-optical structure (4) comprises a first conductive layer (41) and a second conductive layer (42) between which an active layer (6), which comprises the at least one organic, electro-optical material (61), is arranged.

8. The element as claimed in claim 7, wherein at least one of the first and second conductive layers is at least partially transparent.

9. The element as claimed in claim 1, characterized in that the substrate comprises glass.

10. The element as claimed in claim 1, characterized in that the at least one antireflection coating (8, 10) comprises a plurality of layers.

11. The element as claimed in claim 10, wherein the layers (81, 83, 85, 101, 103, 105) have different refractive indices.

12. The element as claimed in claim 10, wherein the antireflection coating (8, 10) has three layers (81, 83, 85, 101, 103, 105).

13. The element as claimed in claim 12, wherein the layers are arranged, starting from the substrate, in a layer sequence of a layer with a medium refractive index (81, 101)/layer with a high refractive index (83, 103)/layer with a low refractive index (85, 105).

14. The element as claimed in claim 10, in which the antireflection coating (10) has at least two layers, and one of the conductive layers (41, 42) is adjacent to the antireflection coating (10), wherein the conductive layer (41, 42) has a refractive index which is less than the refractive indices of the at least two layers of the antireflection coating (10).

15. The element as claimed in claim 1, wherein the antireflection coating (8, 10) has at least one of the following materials: titanium oxide, tantalum oxide, niobium oxide, hafnium oxide, aluminum oxide, silicon oxide, magnesium nitride.

16. The element as claimed in claim 1, wherein the at least one antireflection coating (10) is arranged on the side (22) of the substrate (2) on which the at least one electro-optical structure (4) is applied.

17. The element as claimed in claim 1, wherein at least one adaptation coating (5) is arranged between the antireflection coating (8) and electro-optical structure (4).

18. The element as claimed in claim 1, defined by at least one antireflection coating on the side (21) of the substrate (2) which is opposite the side (22) on which the at least one electro-optical structure (4) is arranged.

19. (canceled)

20. The element (1) as claimed in claim 1, wherein the antireflection coating (10) has light-scattering structures (7).

21. The element as claimed in claim 20, wherein the light-scattering structures (7) comprise at least one of crystals, particles and occlusions in the antireflection coating (10).

22. The element as claimed in claim 1, defined by a structured boundary face with light-scattering structures between the antireflection coating and substrate.

23. The element as claimed in claim 1, defined by an additional layer (11) with light-scattering structures (7).

24. The element as claimed in claim 23, wherein the additional coating (11) has a refractive index which corresponds essentially to the refractive index of the substrate, and the additional layer (11) is arranged on the substrate (2).

25. A method for manufacturing an organic, electro-optical element (1), comprising the steps:
coating at least one side (21, 22) of a substrate (2) with an antireflection coating (8, 10),
and
applying at least one electro-optical structure (4), which comprises at least one organic, electro-optical material (61), where the substrate is coated with an antireflection coating (8, 10) which has at least one layer with a thickness and a refractive index for which the integral reflectivity at the boundary faces of the antireflection coating (10) for light beams emerging for all angles in the active layer and for a wavelength in the spectral range of the emitted light is one of (i) minimal and (ii) at most 25 percent higher than the minimum, the integral reflectivity being the reflectivity which is integrated over all the emission angles of light beams which emerge from the active layer, at the boundary faces of the antireflection coating.

26. The method as claimed in claim 25, wherein the step of applying at least one electro-optical structure (4) comprises the steps:
applying a first conductive layer (41),
applying at least one active layer (6), which comprises the at least one organic, electro-optical material (61), and
applying a second conductive layer (42).

27. The method as claimed in claim 25, wherein the step of coating at least one side (21, 22) of a substrate (2) with an antireflection coating (8, 10) comprises the step of coating with an antireflection coating (8, 10) which has a plurality of layers (81, 83, 85, 101, 103, 105).

28. The method as claimed in claim 25, wherein the step of coating at least one side (21, 22) of a substrate (2) with an antireflection coating (8, 10) comprises the steps:
applying a layer with a medium refractive index (81, 101),
applying a layer with a high refractive index (83, 103), and
applying a layer with a low refractive index (85, 105).

29. The method as claimed in claim 25, wherein the substrate (2) is coated with an antireflection coating (10) which has light-scattering structures (7).

30. The method as claimed in claim 29, wherein an antireflection coating (10) is applied which contains at least one of crystals, particles and occlusions which have a refractive index or orientation which differs from that of the surrounding material.

31. The method as claimed in claim 25, wherein an additional layer (11) with light-scattering structures (7) is applied.

32. The method as claimed in claim 30, wherein the additional layer has a refractive index which corresponds essentially to the refractive index of the substrate, and the additional layer (11) is applied to the substrate.

33. The method as claimed in claim 25, wherein the antireflection coating (10) is applied to a structured side (22) of the substrate (2).

34. The method as claimed in claim 25, wherein the antireflection coating (10) is applied to a roughened side (22) of the substrate (2).

35. The method as claimed in claim 25, wherein the antireflection coating is applied to a side (22) of the substrate (2) which is provided with regular structures.

36. The method as claimed in claim 25, wherein at least one adaptation coating (5) is applied to the antireflection coating (8).

37. The method as claimed in claim 25, wherein the at least one antireflection coating (8, 10) and the at least one electro-optical structure (4) are applied to opposite sides (21, 22) of the substrate (2).

38. The method as claimed in claim 25, wherein antireflection coatings (8, 10) are applied to each side of the substrate (2).

39. The method as claimed in claim 25, wherein the step of coating at least one side (21, 22) of a substrate (2) with an antireflection coating (8, 10) is carried out with one of (i) vacuum coating, (ii) chemical deposition from the gas phase (CVD), (iii) thermally or plasma-enhanced chemical vapor deposition (PECVD) or plasma impulse chemical vapor deposition (PICVD), and (iv) by means of Sol-gel coating, immersion, spray or centrifugal coating.

40. The method as claimed in claim 25, wherein the thickness and the refractive index of the layer for which the integral reflectivity at the boundary faces of the antireflection coating (10) for all the light beams emerging for all angles in the active layer and for a wavelength in the spectral region of the emitted light is one of (i) minimal and (ii) at most 25 percent higher than the minimum, are calculated.

41. A substrate comprising an antireflection coating (8, 10) with at least one layer, wherein the antireflection coating layer has a thickness and a refractive index for which the integral reflectivity at the boundary faces of the antireflection coating is one of: (i) minimal for light beams emerging from the active layer at all angles for a wavelength in the spectral region of the emission spectrum, and (ii) at most 25% higher than the minimum, the integral reflectivity being the reflectivity which is integrated over all the emission angles of light beams which emerge from the active layer, at the boundary faces of the antireflection coating.

42. The substrate as claimed in claim 41 wherein the antireflection coating layer has an optical thickness of at least ⅜ of a wavelength of the transmission spectrum or emission spectrum.

43-46. (canceled)
